(19) United States
(12) Patent Application Publication
(10) Pub. No.: US 2009/0103673 A1
(43) Pub. Date: Apr. 23, 2009

(54) SIGNAL POWER COMBINER WITH DYNAMIC PHASE COMPENSATION

(75) Inventors: TAH-YEONG LIN, TAOYUAN COUNTY (TW); CHUEN-TAI YEH, HSINCHU CITY (TW); CHUNN-YENN LIN, TAOYUAN COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: CHUNG SHAN INSTITUTE OF SCIENCE AND TECHNOLOGY, ARMAMENTS BUREAU, M.N.D., Taoyuan County (TW)

(21) Appl. No.: 11/876,161

(22) Filed: Oct. 22, 2007

(51) Int. Cl. H04L 7/00; H03F 3/68

(52) U.S. Cl. 375/371; 330/124 R

(57) ABSTRACT

The present invention relates to a signal power combiner with dynamic phase compensation, which uses a plurality of phase shifters to receive a first input signal and a second input signal, and shift the phases of the first and second input signals. A detection unit detects the phases of the first input signal and the second input signal, produces a compensation signal, and transmits to the plurality of phase shifters for shifting the phases of the first input signal and the second input signal. A combiner receives the compensated first and second input signals, combines the first input signal and the second input signal, and produces an output signal. Thereby, the transmission quality of signals is improved.

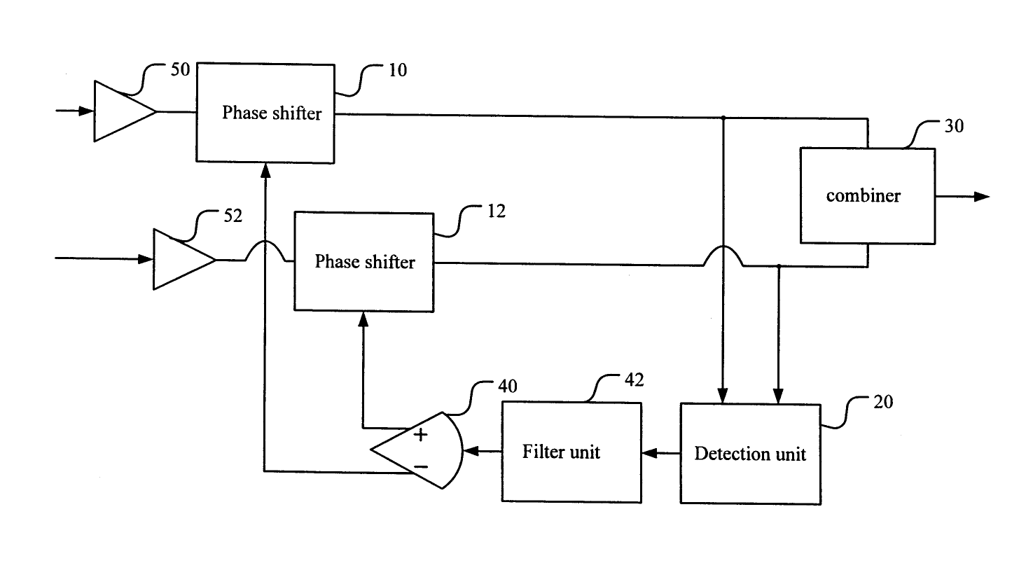

### FIELD OF THE INVENTION

The present invention relates generally to a signal power combiner, and particularly to a signal power combiner with dynamic phase compensation.

### BACKGROUND OF THE INVENTION

In modern popular wireless electronic products, the antenna is an extraordinarily important and indispensable component. The primary function of antenna is to radiate the radio frequency signals produced by the electronic products to the air, or to receive the radio frequency signals in the air to the system of the electronic products. Thereby, the quality and matching characteristics of the antenna used in the electronic products influence substantially both the transmitted and received radio frequency signals. In addition, the performance of the radio frequency(RF) circuits and digital circuits will be influenced as well. Consequently, the designers and manufacturers of the wireless electronic products have to pay special attentions on the influences of the radiation performance of antennas on product systems while designing the antennas or assembling them to the products.

In addition, wireless transmission is adopted in many data extraction equipments that need free mobility. For example, the sensors of a capsule-type endoscope need to enter the human body and cannot transmit signals through wires. Thereby, the sensed physiological parameters or signals are transmitted via a wireless transmitter. Then, a wireless receiver is used to receive the signal outside of the body.

However, in short-range wireless transmission systems, when relative movement and irregular rotation happen between an RF transmitting antenna and a receiving antenna, particularly for small wireless transmission equipments (such as a capsule-type endoscope), because the transmitting antenna is not isotropic and is secured on the transmitting circuitry, the polarity and intensity of the electromagnetic wave of the transmitted signals change according to the movements of the equipments. Thereby, the carrier signal power received by the antenna of the corresponding wireless receiver varies as well, which cause unstable quality of demodulated signals or even interruption of information.

If a single antenna is used for receiving the electromagnetic wave, when the polarity of the electromagnetic wave changes, the power of the antenna output RF signals might vary because of inconsistency between the polarities of the electromagnetic wave and the antenna. In general, an RF power combiner is used for adding RF signals by two or more antennas. However, two problems will happen to deteriorate the performance. The first problem happens when the phases of the two RF signals are opposite with roughly equal amplitudes. The result of addition is reduction in amplitude, which weakens the output power. The second problem is that the amplitudes and phases of the two RF signals vary continuous with the signal source, which is not compensable by fixed amplification and phase-shift circuits.

Accordingly, the present invention provides a novel signal power combiner with dynamic phase compensation, which can perform compensation according to the dynamic phases of the RF signals. Thereby, the respective phases of RF signals of the RF signal power combiner are maintained in-phase and constructive addition is produced. Hence, the transmission quality of signals is improved.

### SUMMARY

An objective of the present invention is to provide a signal power combiner with dynamic phase compensation, which acquires the phase difference between two signals by means of a detection unit, and compensates the input signals by a plurality of phase shifters for improving the transmission quality of signals.

Another objective of the present invention is to provide a signal power combiner with dynamic phase compensation, which adds a plurality of input signals constructively by means of feedback control for automatic phase compensation, and thereby the transmission quality of signals is improved.

The signal power combiner with dynamic phase compensation according to the present invention comprises a plurality of phase shifters, a detection unit, and a combiner. The plurality of phase shifters receives, respectively, a first input signal and a second input signal, and shifts the phases of the first and second input signals. Then, the detection unit detects the shifted phase of the first and second input signals, produces a compensation signal, and sends the compensation signal to the plurality of phase shifters for shifting the phases of the first or second input signals according to the compensation signal. The combiner receives the compensated first and second input signals, combines the first and second input signals via constructive addition, and produces an output signal.

### BRIEF DESCRIPTION OF THE DRAWINGS

The FIGURE shows a block diagram according to a preferred embodiment of the present invention.

### DETAILED DESCRIPTION

In order to make the structure and characteristics as well as the effectiveness of the present invention to be further understood and recognized, the detailed description of the present invention is provided as follows along with preferred embodiments and an accompanying figure.

The FIGURE shows a block diagram according to a preferred embodiment of the present invention. As shown in the figure, the signal power combiner with dynamic phase compensation according to the present invention is illustrated. The present preferred embodiment is applied in, but not limited to, a radio-frequency (RF) receiving circuit of a wireless RF apparatus with multiple antennas. The signal power combiner comprises a plurality of phase shifters 10, 12, a detection unit 20, and a combiner 30. In the present preferred embodiment, dual antennas receiving input signals, respectively, are used for description. However, the present invention is not limited to the present preferred embodiment. The plurality of phase shifters 10, 12 receives a first input signal and a second input signal, respectively. The first and second input signals are RF signals. The plurality of phase shifters 10, 12 is used for shifting the phases of the first and second input signals. The detection unit 20 receives the first and second input signals phase-shifted by the plurality of phase shifters 10, 12, and detects the phases of the first and second input signals. That is to say, the detection unit is a phase detector for detecting the phase difference by which the first input signal leads the second input signal, or for detecting the phase difference by which the first input signal lags the second input signal. Thereby, a compensation signal is produced by the detection unit 20 according to the detected result, and is sent to the plurality of phase shifters 10, 12, respectively. Thus, the plurality of phase shifters 10, 12 can increase the relative phase of the first input signal or the phase of the second input signal according to the compensation signal. Consequently, the compensated first and second input signals will be in phase. Likewise, the relative phase of the first input signal or the phase of the second input signal can be reduced to make the compensated first and second input signals in phase.

The combiner 30 receives the first and second input signals compensated by the plurality of phase shifters 10, 12, and combines said two input signals to produce an output signal. The combiner 30 is a power combiner, which increases the power of the output signal by synthesizing the first and second input signals, so that the quality of the received signal by the RF receiving circuit is stabilized. In addition, for receiving the RF signals using multiple antennas, the reduced received signal quality due to inconsistent signal intensities from respect antennas and uncertainty in phases can be improved. Because the detection unit 20 receives the signals output by the plurality of phase shifters 10, 12 and returns the correction signals back to the plurality of phase shifters 10, 12, the signal power combiner according to the present invention is a negative feedback control circuit with dynamic control. That is, the variations of the phases of input signals are compensated at any time to maintain consistent phases with the input signals entering the combiner 30. Thereby, constructive addition of input signals is maintained in the signal power combiner, and hence the transmission quality is stabilized. Moreover, the signal power combiner with dynamic phase compensation according to the present invention further comprises an operational amplifier 40 and a filter unit 42. The operational amplifier 40 is coupled between the plurality of phase shifters 10, 12 and the detection unit 20, and is used for amplifying the compensation signal outputted by the detection unit 20. In order to prevent noise from being amplified when the operational amplifier 40 amplifies the compensation signal outputted by the detection unit 20 and influences of the background noises, the filter unit 42 is adapted between the operational amplifier 40 and the detection unit 42. The filter unit 42 is used for receiving the compensation signal outputted by the detection unit 20, filtering the compensation signal by eliminating high-frequency noises, and sending to the operational amplifier 40 for amplifying the compensation signal. Besides, the filter unit 42 is a loop filter. In addition to filtering high-frequency noises, the major function thereof is to provide a system, such as a phase-locked loop (PLL), that can control transient responses of the phase changes between the first and second input signals. Moreover, the signal power combiner further comprises a plurality of amplifier 50, 52 coupled to the plurality of phase shifters, 10, 12, respectively, for amplifying the first and second input signals for subsequent circuits. The amplifiers 50, 52 described above are radio-frequency amplifiers.

To sum up, the signal power combiner with dynamic phase compensation according to the present invention uses a detection unit for detecting the phases of a first input signal and a second input signal. According to the phase difference between the two input signals, a compensation signal is produced and sent to a plurality of phase shifters. The phase shifters are radio-frequency phase shifters used for shifting the phases of the first and second input signals according to the compensation signal. Then, a combiner is used for synthesizing said two input signals, and the transmission of the signals is improved.

Accordingly, the present invention conforms to the legal requirements owing to its novelty, non-obviousness, and utility. However, the foregoing description is only a preferred embodiment of the present invention, not used to limit the scope and range of the present invention. Those equivalent changes or modifications made according to the shape, structure, feature, or spirit described in the claims of the present invention are included in the appended claims of the present invention.

1. A signal power combiner with dynamic phase compensation, comprising:
a plurality of phase shifters, receiving a first input signal and a second input signal, respectively, and shifting the phases of the first input signal and the second input signal;
a detection unit, detecting the phases of the first input signal and the second input signal, producing a compensation signal, and sending to the plurality of phase shifters for shifting the phases of the first input signal and the second input signal; and
a combiner, receiving the compensated first and second input signals, synthesizing the first input signal and the second input signal, and producing an output signal.

2. The signal power combiner with dynamic phase compensation of claim 1, and further comprising an operational amplifier, coupled between the plurality of phase shifters and the detection unit for amplifying the compensation and transmitting to the plurality of phase shifters.

3. The signal power combiner with dynamic phase compensation of claim 1, and further comprising a plurality of amplifiers, coupled to the plurality of phase shifters for amplifying the first input signal and the second input signal.

4. The signal power combiner with dynamic phase compensation of claim 3, wherein the amplifiers are radio-frequency amplifiers.

5. The signal power combiner with dynamic phase compensation of claim 1, and further comprising a filter unit, receiving the compensation signal outputted by the detection unit for filtering the compensation signal.

6. The signal power combiner with dynamic phase compensation of claim 1, wherein the detection unit detects the phases of the first input signal and the second input signal, acquiring the phase difference by which the first input signal leads the second input signal, and producing the compensation signal.

7. The signal power combiner with dynamic phase compensation of claim 1, wherein the first input signal and the second input signal are radio-frequency signals.

8. The signal power combiner with dynamic phase compensation of claim 1, wherein the combiner is a power combiner.
